(19) United States
(12) Patent Application Publication
(10) Pub. No.: US 2026/0155162 A1
(43) Pub. Date: Jun. 4, 2026

(54) SENSE AMPLIFIER CIRCUIT

(71) Applicant: Novatek Microelectronics Corp., Hsinchu (TW)

(72) Inventors: Yi-Chia Chen, Taichung City (TW); Chun-Hung Chen, Yunlin County (TW)

(73) Assignee: Novatek Microelectronics Corp., Hsinchu (TW)

(21) Appl. No.: 19/207,387

(22) Filed: May 14, 2025

(30) Foreign Application Priority Data
Dec. 3, 2024 (TW) 113146701

(51) Int. Cl. G11C 7/08; G11C 11/4091

(52) U.S. Cl. CPC G11C 7/08; G11C 11/4091

(57) ABSTRACT

A sense amplifier circuit including a sense amplifier and a control circuit is provided. The sense amplifier is configured to detect input data. The control circuit is coupled to the sense amplifier. The control circuit outputs a control signal to control the sense amplifier to detect the input data. The control circuit controls whether the sense amplifier performs a pre-charge operation or a pre-discharge operation based on the input data of a previous cycle and a current cycle.

### CROSS-REFERENCE TO RELATED APPLICATION

This application claims the priority benefit of Taiwan application serial no. 113146701, filed on Dec. 3, 2024. The entirety of the above-mentioned patent application is hereby incorporated by reference herein and made a part of this specification.

### BACKGROUND

### Technical Field

The disclosure relates to an electronic circuit, and particularly relates to a sense amplifier circuit.

### Description of Related Art

A source driver device is a driving circuit used to control operations of a display panel. The display panel may be, for example, a liquid crystal display (LCD) or an organic light-emitting diode (OLED) panel. The source driver device may provide display data to the display panel to control each pixel or sub-pixel on the display panel to display a target brightness, so as to display a corresponding image. The source driver device may include a plurality of channels, and each channel is used to provide display data to a column of sub-pixels on the display panel. An output terminal of each channel is usually configured with an amplifier to drive a corresponding data line on the display panel to reach a target voltage.

### SUMMARY

The disclosure is directed to a sense amplifier circuit adapted to determine whether to perform a pre-charge operation or a pre-discharge operation based on input data to achieve a power saving effect.

An embodiment of the disclosure provides a sense amplifier circuit including a sense amplifier and a control circuit. The sense amplifier is configured to detect input data. The control circuit is coupled to the sense amplifier. The control circuit outputs a control signal to control the sense amplifier to detect the input data. The control circuit controls whether the sense amplifier performs a pre-charge operation or a pre-discharge operation based on the input data of a previous cycle and a current cycle.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a block schematic diagram of a sense amplifier circuit according to an embodiment of the disclosure.

FIG. 2 is a schematic diagram of an internal structure of the sense amplifier circuit of the embodiment of FIG. 1.

FIG. 3 is a waveform diagram of input signals and clock signals according to an embodiment of the disclosure.

FIG. 4 is a waveform diagram of input signals and clock signals according to another embodiment of the disclosure.

FIG. 5A is an operational schematic diagram of a sense amplifier circuit in each phase when input data are different in a previous cycle and a current cycle according to an embodiment of the disclosure.

FIG. 5B is a schematic diagram of waveforms of the input data and control signals in the embodiment of FIG. 5A.

FIG. 5C is a schematic diagram of an internal structure of a control circuit according to an embodiment of the disclosure.

FIG. 5D is a schematic diagram of an internal structure of a control circuit according to another embodiment of the disclosure.

FIG. 6A is an operational schematic diagram of a sense amplifier circuit in each phase when the input data are the same in the previous cycle and the current cycle according to another embodiment of the disclosure.

FIG. 6B is a schematic diagram of waveforms of input data and control signals in the embodiment of FIG. 6A.

FIG. 7A is an operational schematic diagram of a sense amplifier circuit in each phase when the input data are the same in the previous cycle and the current cycle according to another embodiment of the disclosure.

FIG. 7B is a schematic diagram of waveforms of input data and control signals in the embodiment of FIG. 7A.

FIG. 8A is an operational schematic diagram of a sense amplifier circuit in each phase when the input data are the same in the previous cycle and the current cycle according to another embodiment of the disclosure.

FIG. 8B is a schematic diagram of waveforms of input data and control signals in the embodiment of FIG. 8A.

FIG. 9 is a schematic diagram of an internal structure of a sense amplifier according to an embodiment of the disclosure.

FIG. 10 is a schematic diagram of an internal structure of a sense amplifier according to another embodiment of the disclosure.

### DESCRIPTION OF THE EMBODIMENTS

Before a sense amplifier circuit detects input data, the circuit itself needs to be pre-charged or pre-discharged, and output nodes on both sides of the circuit are reset to an initial state before detecting the input data. Generally, the output nodes on both sides need to be pre-charged or pre-discharged in each cycle. However, if the input data of a current cycle is the same as the input data of a previous cycle, again pre-charging or pre-discharging of the output nodes on both sides may cause unnecessary power consumption. In order to reduce the unnecessary power consumption, the disclosure provides several methods, which are described in detail below.

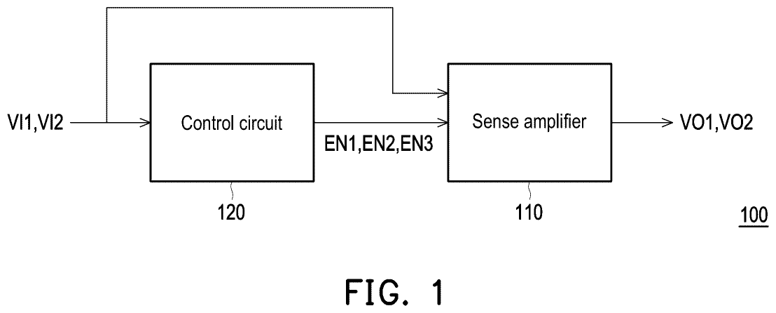

FIG. 1 is a block schematic diagram of a sense amplifier circuit according to an embodiment of the disclosure. Referring to FIG. 1, a sense amplifier circuit 100 includes a sense amplifier 110 and a control circuit 120. The control circuit 120 is coupled to the sense amplifier 110.

The sense amplifier 110 is configured to detect input data VI1, VI2, and output output data VO1, VO2. The control circuit 120 is configured to output at least one control signal EN1, EN2, EN3 to control the sense amplifier 110. The number of the control signals may be adjusted according to a circuit structure of the sense amplifier 110, which is not limited by the disclosure. The control circuit 120 may control whether the sense amplifier 110 performs a pre-charge operation or a pre-discharge operation according to the input data VI1 and VI2 of the previous cycle and the current cycle.

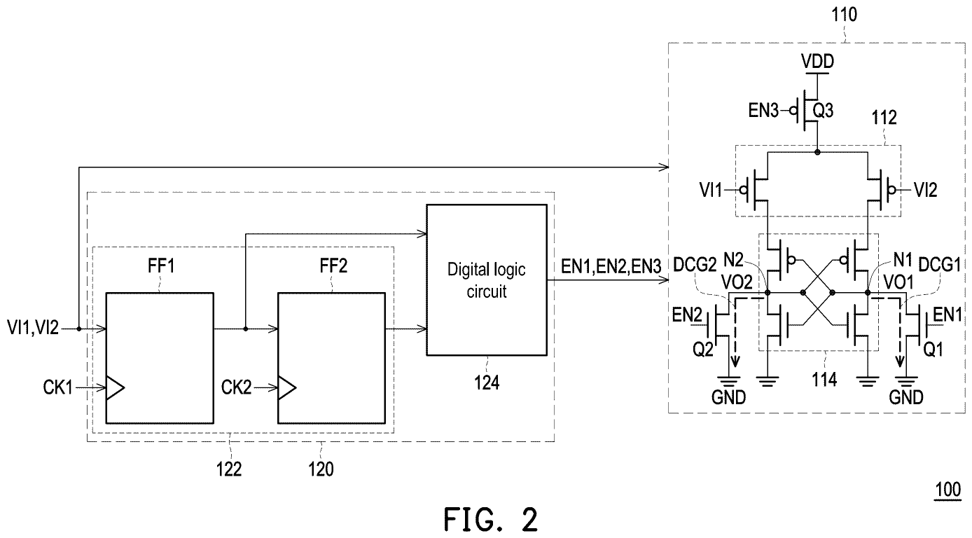

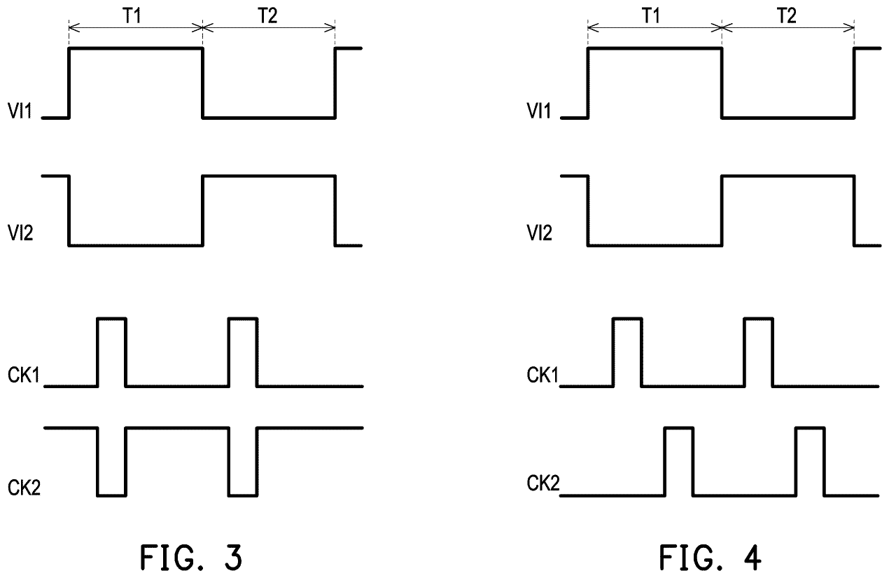

Specifically, FIG. 2 is a schematic diagram of an internal structure of the sense amplifier circuit of the embodiment of FIG. 1. FIG. 3 is a waveform diagram of input signals and clock signals according to an embodiment of the disclosure. Referring to FIG. 2 and FIG. 3, in the embodiment, the sense amplifier 110 is, for example, a P-input type sense amplifier (first type sense amplifier). In another embodiment, the sense amplifier 110 is, for example, an N-input type sense amplifier (second type sense amplifier). The disclosure does not limit the type of the sense amplifier.

Taking the P-input type sense amplifier of FIG. 2 as an example, the sense amplifier 110 includes an input stage unit 112, a latch unit 114, and a plurality of transistor switches Q1, Q2, and Q3. The input stage unit 112 is configured to receive the input data VI1, VI2. Where, the input data VI1 and VI2 are data inverted to each other. The latch unit 114 is configured to output the output data VO1, VO2. The latch unit 114 is coupled to a first voltage GND through the transistor switches Q1 and Q2, and the input stage unit 112 is coupled to a second voltage VDD through the transistor switch Q3. The first voltage GND is, for example, a ground voltage. The second voltage VDD is, for example, a system operating voltage. Where, the second voltage VDD is greater than the first voltage GND. The disclosure does not limit voltage values of the first voltage and the second voltage.

Further, the sense amplifier 110 includes pre-discharge paths DCG1, DCG2. The transistor switches Q1 and Q2 are respectively disposed on the pre-discharge paths DCG1 and DCG2. A first terminal of the transistor switch Q1 is coupled to an output node N1 of the sense amplifier 110, a second terminal of the transistor switch Q1 is coupled to the first voltage GND, and a control terminal of the transistor switch Q1 is coupled to the control circuit 120 to receive the control signal EN1. A first terminal of the transistor switch Q2 is coupled to an output node N2 of the sense amplifier 110, a second terminal of the transistor switch Q2 is coupled to the first voltage GND, and a control terminal of the transistor switch Q2 is coupled to the control circuit 120 to receive the control signal EN2. The transistor switch Q3 is coupled between the second voltage VDD and the input stage unit 112. A control terminal of the transistor switch Q3 is coupled to the control circuit 120 to receive the control signal EN3.

The control circuit 120 may control whether the sense amplifier 110 performs a pre-discharge operation through the transistor switches Q1 and Q2. Specifically, the control circuit 120 controls conduction states of the transistor switches Q1, Q2, and Q3 respectively through the control signals EN1, EN2, and EN3, so that the sense amplifier 110 may perform or not perform the pre-discharge operation according to the input data VI1, VI2. Taking the pre-discharge path DCG1 as an example, when the transistor switch Q1 is turned on, the first voltage GND performs a pre-discharge operation on the output node N1. When the transistor switch Q1 is not turned on, the sense amplifier 110 does not perform the pre-discharge operation.

Furthermore, the control circuit 120 includes a flip-flop circuit 122 and a digital logic circuit 124. The digital logic circuit 124 is coupled to flip-flop circuit 122. The flip-flop circuit 122 is configured to store and record the input data VI1 and VI2 of the previous cycle T1 and the current cycle T2. The digital logic circuit 124 is configured to output the control signals EN1, EN2 and EN3 according to the input data VI1 and VI2 of the previous cycle T1 and the current cycle T2.

The flip-flop circuit 122 includes a first flip-flop FF1 and a second flip-flop FF2. The first flip-flop FF1 and the second flip-flop FF2 form a master-slave flip-flop framework. The first flip-flop FF1 is configured to store and record the input data VI1 and VI2 of the current cycle T2. The second flip-flop FF2 is configured to store and record the input data VI1 and VI2 of the previous cycle T1. In the embodiment, the clock signals CK1 and CK2 are synchronization signals, and the first flip-flop FF1 and the second flip-flop FF2 are, for example, positive-edge triggered flip-flops. FIG. 4 is a waveform diagram of input signals and clock signals according to another embodiment of the disclosure. In the embodiment of FIG. 4, the clock signals CK1 and CK2 are asynchronous signals.

The control circuit 120 includes at least the following two control methods. The first control method is: taking the input data VI1 as an example, when the input data VI1 is different in former and later cycles, the output nodes N1 and N2 respectively perform pre-discharge operations through the pre-discharge paths DCG1 and DCG2 on both sides. At this time, bit values of the control signals EN1, EN2 and EN3 are all 1. When the input data VI1 are the same in former and later cycles, the output nodes N1 and N2 do not perform the pre-discharge operations. At this time, the bit values of the control signals EN1, EN2, and EN3 are all 0. Where, the bit value 1 is logic high, and the bit value 0 is logic low.

Namely, in the first control method, when the input data VI1 is different in the previous cycle T1 and the current cycle T2, the control circuit 120 may control the sense amplifier 110 to perform a pre-discharge operation. When the input data VI1 of the previous cycle T1 and the current cycle T2 are the same, the control circuit 120 may control the sense amplifier 110 not to perform the pre-discharge operation.

The second control method is: when the input data VI1 is different in former and later cycles, the output nodes N1 and N2 also perform pre-discharge operations through the pre-discharge paths DCG1 and DCG2 on both sides respectively. At this time, bit values of the control signals EN1, EN2 and EN3 are all 1. When the input data VI1 are the same in former and later cycles and the bit values are 0, only the output node N1 performs a single-side pre-discharge operation. At this time, the bit values of the control signals EN1, EN2, and EN3 are 1, 0, and 1 respectively; when the input data VI1 are the same in former and later cycles and the bit values are 1, only the output node N2 performs the single-side pre-discharge operation. At this time, the bit values of the control signals EN1, EN2, and EN3 are 0, 1, and 1 respectively.

Namely, in the second control mode, when the input data VI1 is different in the previous cycle T1 and the current cycle T2, the control circuit 120 may control the sense amplifier 110 to perform the pre-discharge operation. When the input data VI1 of the previous cycle T1 and the current cycle T2 are the same, the control circuit 120 may control the sense amplifier 110 to perform the single-side pre-discharge operation.

Therefore, in FIG. 2, taking the P-input type sense amplifier as an example, in order to avoid unnecessary power consumption by the sense amplifier 110, the control circuit 120 uses a master-slave flip-flop framework to record the input data VI1 and VI2 of the previous cycle T1 and the current cycle T2, and perform data comparison through the digital logic circuit 124, so as to control the pre-discharge operation of the sense amplifier 110 to achieve a power saving effect.

The following uses a P-input type sense amplifier as an example to illustrate operation modes of the sense amplifier 110 in each phase.

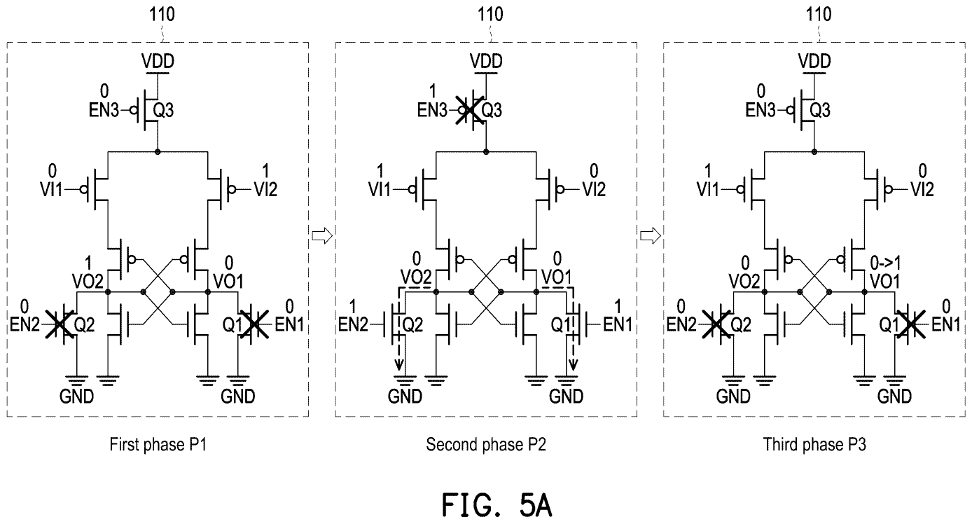

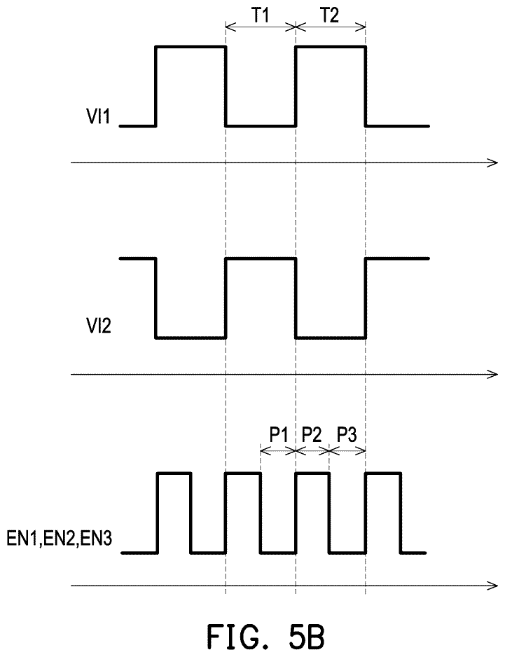

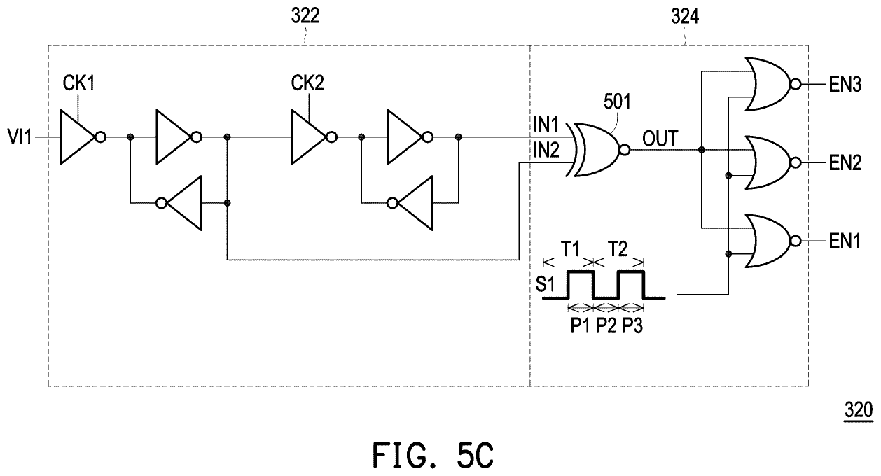

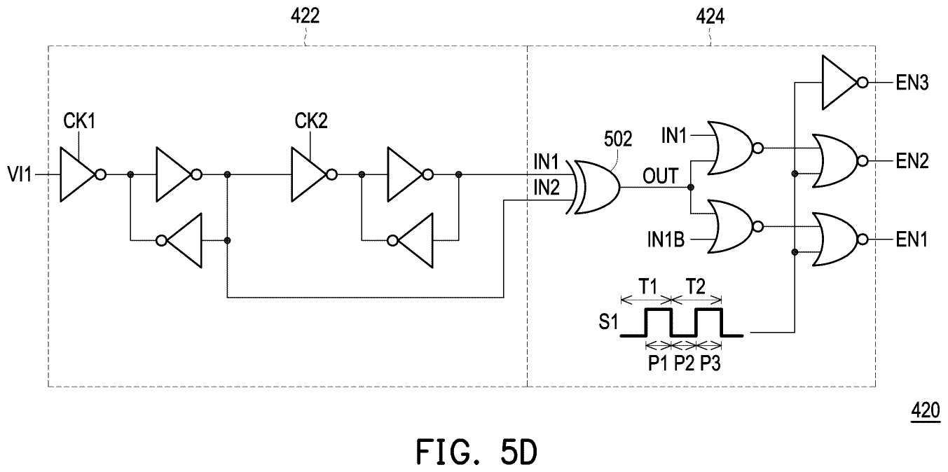

FIG. 5A is an operational schematic diagram of a sense amplifier circuit in each phase when input data is different in the previous cycle and the current cycle according to an embodiment of the disclosure. FIG. 5B is a schematic diagram of waveforms of the input data and control signals in the embodiment of FIG. 5A. Referring to FIG. 5A and FIG. 5B, in the example, the input data VI1 is different in the previous cycle T1 and the current cycle T2, and is 0 and 1, respectively. Since the input data VI1 and VI2 are inverse data of each other, the input data VI2 are also different in the previous cycle T1 and the current cycle T2, which are 1 and 0, respectively.

In a first phase, the sense amplifier 110 detects the input data VI1 and VI2 in the previous cycle T1. At this time, the bit values of the control signals EN1, EN2, and EN3 are all 0, the transistor switches Q1 and Q2 are not turned on, and the transistor switch Q3 is turned on. In a second phase, the sense amplifier 110 performs a pre-discharge operation in the current cycle T2. At this time, the bit values of the control signals EN1, EN2, and EN3 are all 1, the transistor switches Q1 and Q2 are turned on, and the transistor switch Q3 is not turned on. In a third phase, the sense amplifier 110 detects the input data VI1 and VI2 in the current cycle T2. At this time, the bit values of the control signals EN1, EN2, and EN3 are all 0, the transistor switches Q1 and Q2 are not turned on, and the transistor switch Q3 is turned on. The input data VI1 and VI2 detected by the sense amplifier 110 in the current cycle T2 are 1 and 0 respectively, which are different from the input data VI1 and VI2 detected in the previous cycle T1.

FIG. 5C is a schematic diagram of an internal structure of a control circuit according to an embodiment of the disclosure. A control circuit 320 of FIG. 5C may be used to generate the control signals EN1, EN2, EN3 of FIG. 5B. Referring to FIG. 5A to FIG. 5C, the control circuit 320 includes a flip-flop circuit 322 with a master-slave flip-flop framework and a digital logic circuit 324. The digital logic circuit 324 may generate the control signals EN1, EN2, and EN3 according to a digital signal S1.

Specifically, the following table 1 is a truth table of an exclusive NOR gate (XNOR) 501:

TABLE 1

| | Column | IN1 | IN2 | OUT |
|---|---|---|---|---|
| XNOR | 1 | 0 | 0 | 1 |
| | 2 | 0 | 1 | 0 |
| | 3 | 1 | 0 | 0 |
| | 4 | 1 | 1 | 1 |

Where, IN1 represents input data of the previous cycle T1 received by the XNOR 501; IN2 represents input data of the current cycle T2 received by the XNOR 501; OUT is output data of the XNOR 501. In addition, corresponding to a first phase P1, a second phase P2, and a third phase P3 of FIG. 5A, the digital signal S1 has bit values 1, 0, and 1 respectively.

In FIG. 5C, taking the input data VI1 as an example, since the input data VI1 is different in the previous cycle T1 and the current cycle T2, it may correspond to a 2nd or 3rd column of Table 1, an output of the XNOR 501 is 0, so that the digital logic circuit 324 may generate the control signals EN1, EN2, and EN3 according to the digital signal S1, and bit values thereof are opposite to the digital signal S1, which are respectively 0, 1, 0 in the first phase P1, the second phase P2, and the third phase P3, as shown in FIG. 5B. In this way, the control circuit 320 may control the sense amplifier 110 to respectively perform a data detection operation, a pre-discharge operation, and a data detection operation in the first phase P1, the second phase P2, and the third phase P3.

FIG. 5D is a schematic diagram of an internal structure of a control circuit according to another embodiment of the disclosure. A control circuit 420 of FIG. 5D may also be used to generate the control signals EN1, EN2, and EN3 of FIG. 5B. Referring to FIG. 5A, FIG. 5B and FIG. 5D, the control circuit 420 includes a flip-flop circuit 422 and a digital logic circuit 424. In the embodiment, the flip-flop circuit 422 also has a master-slave flip-flop framework, but the circuit structure of the digital logic circuit 424 is different from that of the digital logic circuit 324.

To be specific, a following Table 2 is a truth table of an exclusive OR gate (XOR) 502:

TABLE 2

| | Column | IN1 | IN2 | OUT |
|---|---|---|---|---|
| XOR | 1 | 0 | 0 | 0 |
| | 2 | 0 | 1 | 1 |
| | 3 | 1 | 0 | 1 |
| | 4 | 1 | 1 | 0 |

Where, IN1 represents input data of the previous cycle T1 received by the XOR 502; IN2 represents input data of the current cycle T2 received by the XOR 502; OUT is output data of the XOR 502.

In FIG. 5D, taking the input data VI1 as an example, since the input data VI1 is different in the previous cycle T1 and the current cycle T2, it may correspond to a 2nd or 3rd column of Table 2, an output of the XOR 502 is 1, so that the digital logic circuit 424 may generate the control signals EN1, EN2, EN3 based on the input data IN1 of the previous cycle T1, inverse data IN1B thereof and the digital signal S1, and bit values thereof are respectively 0, 1 and 0 in the first phase P1, the second phase P2, and the third phase, as shown in FIG. 5B. In this way, the control circuit 420 may control the sense amplifier 110 to respectively perform the data detection operation, the pre-discharge operation, and the data detection operation in the first phase P1, the second phase P2, and the third phase P3.

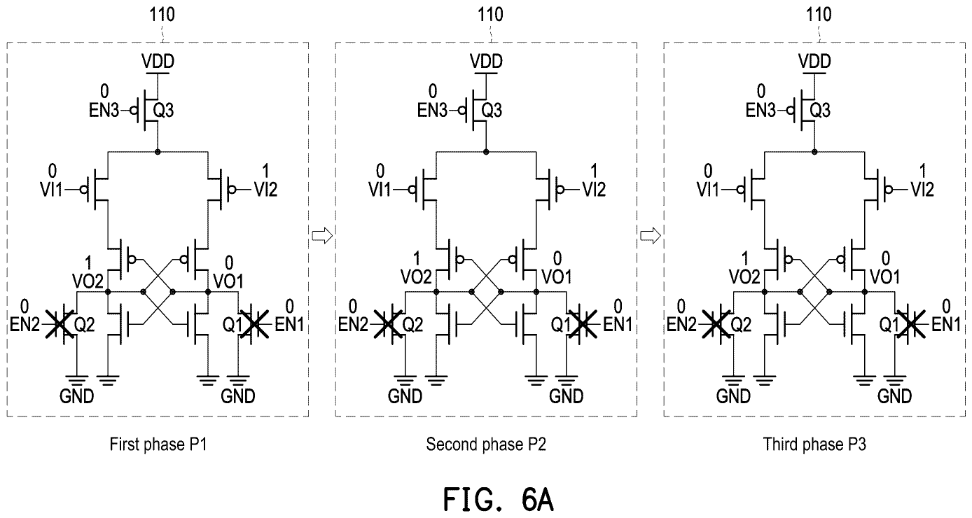

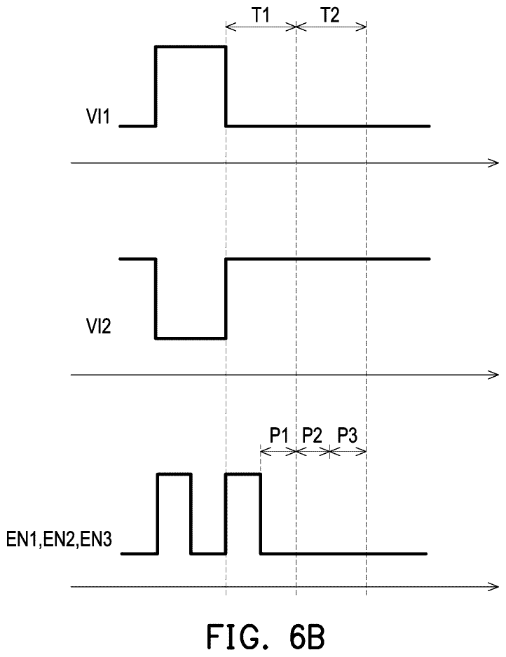

FIG. 6A is an operational schematic diagram of a sense amplifier circuit in each phase when the input data are the same in the previous cycle and the current cycle according to another embodiment of the disclosure, which corresponds to the first control method mentioned above. FIG. 6B is a schematic diagram of waveforms of input data and control signals in the embodiment of FIG. 6A. Referring to FIG. 6A and FIG. 6B, in the example, the input data VI1 are the same in the previous cycle T1 and the current cycle T2, which are 0 in both cycles. Since the input data VI1 and VI2 are inverse data of each other, the input data VI2 are also the same in the previous cycle T1 and the current cycle T2, which are 1 in both cycles.

In the first phase, the sense amplifier 110 detects the input data VI1 and VI2 in the previous cycle T1. At this time, the bit values of the control signals EN1, EN2, and EN3 are all 0, the transistor switches Q1 and Q2 are not turned on, and the transistor switch Q3 is turned on. In the second phase, since the input data VI1 are the same in the previous cycle T1 and the current cycle T2, the sense amplifier 110 does not perform the pre-discharge operation in the current cycle T2 to achieve the power saving effect. At this time, the bit values of the control signals EN1, EN2, and EN3 are all 0, the transistor switches Q1 and Q2 are not turned on, and the transistor switch Q3 is turned on. In the third phase, the sense amplifier 110 detects the input data VI1 and VI2 in the current cycle T2. At this time, the bit values of the control signals EN1, EN2, and EN3 are all 0, the transistor switches Q1 and Q2 are not turned on, and the transistor switch Q3 is turned on. The input data VI1 and VI2 detected by the sense amplifier 110 in the current cycle T2 are 0 and 1 respectively, which are the same as the input data VI1 and VI2 detected in the previous cycle T1.

On the other hand, the control circuit 320 of FIG. 5C may also be used to generate the control signals EN1, EN2, and EN3 of FIG. 6B. Taking the input data VI1 as an example, since the input data VI1 are the same in the previous cycle T1 and the current cycle T2, it may correspond to a column 1 or column 4 of Table 1, and the output of the XNOR 501 is 1, so that in the first phase P1, the second phase P2, and the third phase P3, the digital logic circuit 324 may generate the control signals EN1, EN2, and EN3 with bit values being all 0, as shown in FIG. 6B. In this way, the control circuit 320 may control the sense amplifier 110 not to perform the pre-discharge operation in the second phase P2.

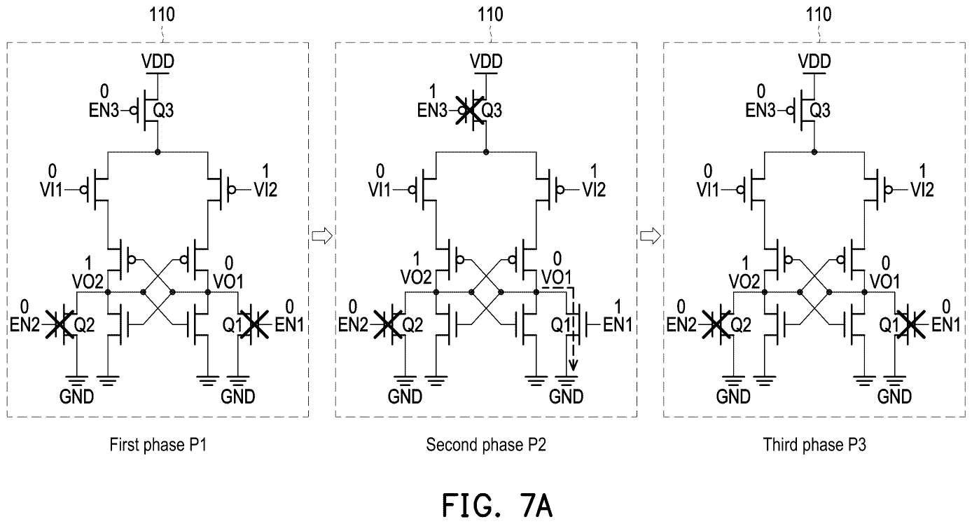

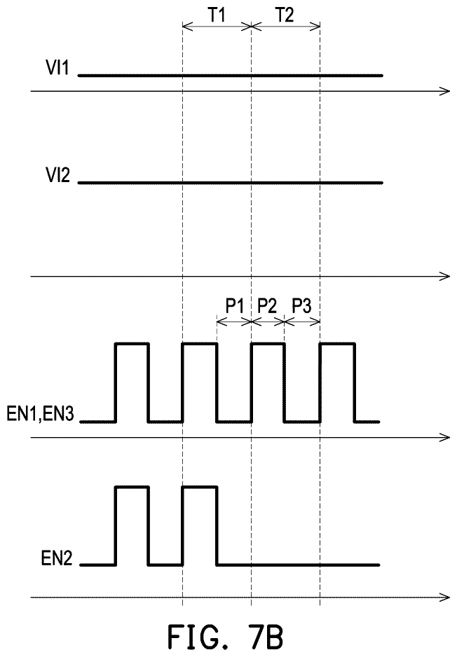

FIG. 7A is an operational schematic diagram of a sense amplifier circuit in each phase when the input data are the same in the previous cycle and the current cycle according to another embodiment of the disclosure, which corresponds to the second control method mentioned above. FIG. 7B is a schematic diagram of waveforms of input data and control signals in the embodiment of FIG. 7A. Referring to FIG. 7A and FIG. 7B, in the example, the input data VI1 are the same in the previous cycle T1 and the current cycle T2, which are 0 in both cycles. Since the input data VI1 and VI2 are inverse data of each other, the input data VI2 are also the same in the previous cycle T1 and the current cycle T2, which are 1 in both cycles.

In the first phase, the sense amplifier 110 detects the input data VI1 and VI2 in the previous cycle T1. At this time, the bit values of the control signals EN1, EN2, and EN3 are all 0, the transistor switches Q1 and Q2 are not turned on, and the transistor switch Q3 is turned on.

In the second phase, since the input data VI1 are the same in the previous cycle T1 and the current cycle T2, which are 0 in both cycles, only the output node N1 of the sense amplifier 110 perform a single-side pre-discharge operation in the current cycle T2, so as to achieve the power saving effect. At this time, the bit values of the control signals EN1 and EN3 are 1, and the bit value of the control signal EN2 is 0. The transistor switch Q1 is turned on, and the transistor switches Q2 and Q3 are not turned on. In the third phase, the sense amplifier 110 detects the input data VI1 and VI2 in the current cycle T2. At this time, the bit values of the control signals EN1, EN2, and EN3 are all 0, the transistor switches Q1 and Q2 are not turned on, and the transistor switch Q3 is turned on. The input data VI1 and VI2 detected by the sense amplifier 110 in the current cycle T2 are 0 and 1 respectively, which are the same as the input data VI1 and VI2 detected in the previous cycle T1.

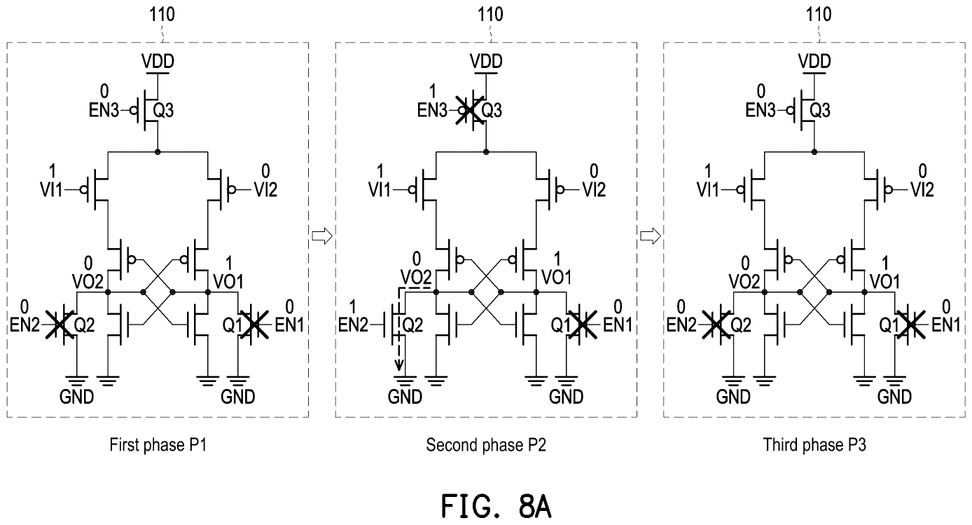

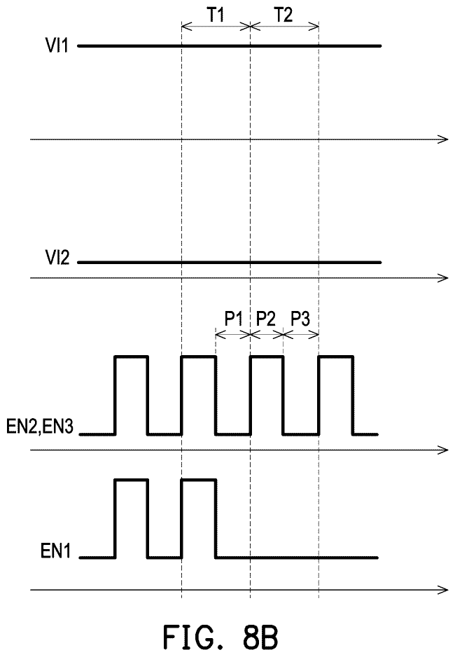

FIG. 8A is an operational schematic diagram of a sense amplifier circuit in each phase when the input data are the same in the previous cycle and the current cycle according to another embodiment of the disclosure, which corresponds to the second control method mentioned above. FIG. 8B is a schematic diagram of waveforms of input data and control signals in the embodiment of FIG. 8A. Referring to FIG. 8A and FIG. 8B, in the example, the input data VI1 are the same in the previous cycle T1 and the current cycle T2, which are 1 in both cycles. Since the input data VI1 and VI2 are inverse data of each other, the input data VI2 are also the same in the previous cycle T1 and the current cycle T2, which are 0 in both cycles.

In the first phase, the sense amplifier 110 detects the input data VI1 and VI2 in the previous cycle T1. At this time, the bit values of the control signals EN1, EN2, and EN3 are all 0, the transistor switches Q1 and Q2 are not turned on, and the transistor switch Q3 is turned on. In the second phase, since the input data VI1 are the same in the previous cycle T1 and the current cycle T2, which are 1 in both cycles, only the output node N2 of the sense amplifier 110 perform a single-side pre-discharge operation in the current cycle T2, so as to achieve the power saving effect. At this time, the bit value of the control signal EN1 is 0, and the bit values of the control signals EN2 and EN3 are 1. The transistor switches Q1 and Q3 are not turned on, and the transistor switch Q2 is turned on. In the third phase, the sense amplifier 110 detects the input data VI1 and VI2 in the current cycle T2. At this time, the bit values of the control signals EN1, EN2, and EN3 are all 0, the transistor switches Q1 and Q2 are not turned on, and the transistor switch Q3 is turned on. The input data VI1 and VI2 detected by the sense amplifier 110 in the current cycle T2 are 1 and 0 respectively, which are the same as the input data VI1 and VI2 detected in the previous cycle T1.

On the other hand, the control circuit 420 of FIG. 5D may also be used to generate the control signals EN1, EN2, and EN3 of FIG. 7B. Taking the input data VI1 as an example, since the input data VI1 are the same in the previous cycle T1 and the current cycle T2, it may correspond to a column 1 or column 4 of Table 2, the output of the XOR 502 is 0, and the digital logic circuit 424 may generate the control signals EN1, EN2, and EN3 with bit values as shown in FIG. 7B and FIG. 8B in the first phase P1, the second phase P2, and the third phase P3. In this way, the control circuit 420 may control the sense amplifier 110 to perform the single-side pre-discharge operation in the second phase P2.

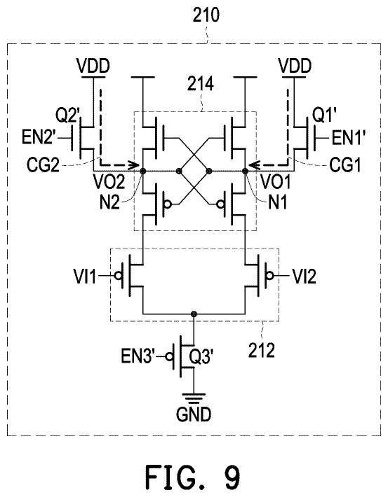

FIG. 9 is a schematic diagram of an internal structure of a sense amplifier according to an embodiment of the disclosure. Referring to FIG. 9, in the embodiment, a sense amplifier 210 is, for example, an N-input type sense amplifier. The sense amplifier 210 determines whether to perform a pre-charge operation based on the input data VI1 and VI2 of the previous cycle T1 and the current cycle T2.

The sense amplifier 210 includes an input stage unit 212, a latch unit 214, and a plurality of transistor switches Q1′, Q2′, and Q3′. The input stage unit 212 is configured to receive the input data VI1, VI2. The latch unit 214 is configured to output output data VO1, VO2. The latch unit 214 is coupled to the second voltage VDD through the transistor switches Q1′, Q2′, and the input stage unit 212 is coupled to the first voltage GND through the transistor switch Q3′.

The sense amplifier 210 includes pre-charge paths CG1 and CG2. The transistor switches Q1′ and Q2′ are respectively disposed on the pre-charge paths CG1 and CG2. A first terminal of the transistor switch Q1′ is coupled to the second voltage VDD, a second terminal of the transistor switch Q1′ is coupled to the output node N1 of the sense amplifier 210, and a control terminal of the transistor switch Q1′ is coupled to the control circuit 120 to receive the control signal EN1′. A first terminal of the transistor switch Q2′ is coupled to the second voltage VDD, a second terminal of the transistor switch Q2′ is coupled to the output node N2 of the sense amplifier 210, and a control terminal of the transistor switch Q2′ is coupled to the control circuit 120 to receive the control signal EN2′. The transistor switch Q3′ is coupled between the input stage unit 212 and the first voltage GND. A control terminal of the transistor switch Q3′ is coupled to the control circuit 120 to receive the control signal EN3′.

The control circuit 120 may control whether the sense amplifier 210 performs a pre-charge operation through the transistor switches Q1′ and Q2′. Specifically, the control circuit 120 controls conduction states of the transistor switches Q1′, Q2′, and Q3′ through the control signals EN1′, EN2′, and EN3′ respectively, so that the sense amplifier 210 may perform or not perform the pre-charge operation according to the input data VI1, VI2. Taking the pre-charge path CG1 as an example, when the transistor switch Q1′ is turned on, the second voltage VDD performs the pre-charge operation on the output node N1. When the transistor switch Q1′ is not turned on, the sense amplifier 210 does not perform the pre-charge operation.

Regarding the operation mode of the sense amplifier 210 in each phase of the embodiment, sufficient teachings, suggestions and implementation instructions may be obtained from the descriptions of the embodiment of FIG. 5A to FIG. 8B, and therefore detail thereof is not repeated.

The sense amplifier circuit 100 of the embodiment of the disclosure may be applied to a display driver circuit, such as a data driver or a source driver. The sense amplifier 110 may also be used as a potential converter of the display driver circuit to convert the low-voltage input data VI1 and VI2 into the medium-voltage output data VO1 and VO2. The output data VO1 and VO2 may be output to a digital-to-analog converter circuit or the source driver circuit in the display driver circuit to serve as a selection signal to select a gray-scale voltage. The sense amplifier circuit 100 may determine whether to perform a pre-charge operation or a pre-discharge operation based on the input data VI1 and VI2, so that the display driver circuit may have the power saving effect.

In an application example of the display driver circuit, since the transistor switch Q3 may be designed as a medium-voltage component, in order to effectively control the conduction state of the transistor switch Q3, the sense amplifier circuit 100 may further include a potential converter, which is used to convert the control signal EN3 into a medium-voltage signal.

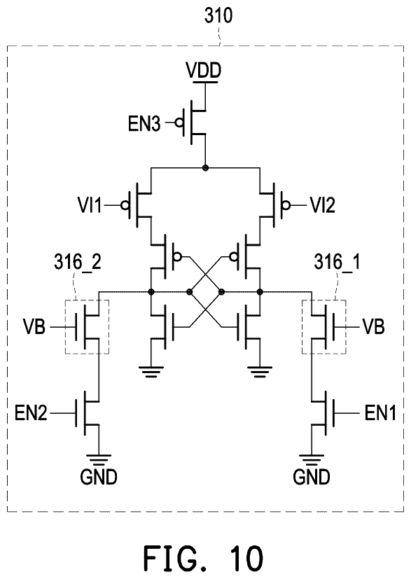

FIG. 10 is a schematic diagram of an internal structure of a sense amplifier according to another embodiment of the disclosure. Referring to FIG. 10, in the embodiment, a sense amplifier 310 is, for example, a P-input type sense amplifier, and a circuit framework thereof is a composite framework of medium-voltage components and low-voltage components. For example, the transistor components corresponding to the control signals EN1 and EN2 are low-voltage components, and the remaining transistor components are medium-voltage components.

In an application example of the display driver circuit, the sense amplifier 310 may further include cascade transistors 316_1 and 316_2. The cascade transistors 316_1 and 316_2 are medium-voltage components, and voltages at drain terminals of the transistor components corresponding to the lower control signals EN1 and EN2 may be limited by providing an appropriate third voltage VB, so as avoid excessive voltage difference between a drain and a source of the transistor component to cause damage to the transistor component itself.

In addition, the sense amplifier circuit 100 according to the embodiment of the disclosure may also be used as a sense amplifier in a memory circuit. The sense amplifier circuit 100 may determine whether to perform a pre-charge operation or a pre-discharge operation based on the input data VI1 and VI2, so that the memory circuit may have the power saving effect.

In summary, in embodiments of the disclosure, the sense amplifier circuit may decide whether to perform a pre-charge operation or a pre-discharge operation based on input data, thereby achieving a power saving effect regardless of being applied in a display driver circuit or a memory circuit.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A sense amplifier circuit, comprising:
a sense amplifier, configured to detect input data; and
a control circuit, coupled to the sense amplifier, and configured to output a control signal to control the sense amplifier to detect the input data,
wherein the control circuit controls whether the sense amplifier performs a pre-charge operation or a pre-discharge operation based on the input data of a previous cycle and a current cycle.

2. The sense amplifier circuit according to claim 1, wherein when the input data of the previous cycle and the current cycle are the same, the control circuit controls the sense amplifier not to perform the pre-charge operation or the pre-discharge operation.

3. The sense amplifier circuit according to claim 1, wherein when the input data of the previous cycle and the current cycle are the same, the control circuit controls the sense amplifier to perform a single-side pre-charge operation or a single-side pre-discharge operation.

4. The sense amplifier circuit according to claim 1, wherein when the input data of the previous cycle and the current cycle are different, the control circuit controls the sense amplifier to perform the pre-charge operation or the pre-discharge operation.

5. The sense amplifier circuit according to claim 1, wherein the sense amplifier is a first-type sense amplifier, and the control circuit controls whether the sense amplifier performs the pre-discharge operation based on the input data of the previous cycle and the current cycle.

6. The sense amplifier circuit according to claim 5, wherein the sense amplifier comprises at least one pre-discharge path, the pre-discharge path comprises a transistor switch, and the control circuit controls whether the sense amplifier performs the pre-discharge operation through the transistor switch.

7. The sense amplifier circuit according to claim 6, wherein the transistor switch comprises a first terminal, a second terminal, and a control terminal, the first terminal is coupled to an output node of the sense amplifier, the second terminal is coupled to a first voltage, and the control terminal is coupled to the control circuit to receive the control signal.

8. The sense amplifier circuit according to claim 7, wherein
when the transistor switch is turned on, the first voltage performs the pre-discharge operation on the output node; and
when the transistor switch is not turned on, the sense amplifier does not perform the pre-discharge operation.

9. The sense amplifier circuit according to claim 1, wherein the sense amplifier is a second type sense amplifier, and the control circuit controls whether the sense amplifier performs the pre-charge operation based on the input data of the previous cycle and the current cycle.

10. The sense amplifier circuit according to claim 9, wherein the sense amplifier comprises at least one pre-charge path, the pre-charge path comprises a transistor switch, and the control circuit controls whether the sense amplifier performs the pre-charge operation through the transistor switch.

11. The sense amplifier circuit according to claim 10, wherein the transistor switch comprises a first terminal, a second terminal, and a control terminal, the first terminal is coupled to a second voltage, the second terminal is coupled to an output node of the sense amplifier, and the control terminal is coupled to the control circuit to receive the control signal.

12. The sense amplifier circuit according to claim 11, wherein
when the transistor switch is turned on, the second voltage performs the pre-charge operation on the output node; and
when the transistor switch is not turned on, the sense amplifier does not perform the pre-charge operation.

13. The sense amplifier circuit according to claim 1, wherein the control circuit comprises:
a flip-flop circuit, configured to store the input data of the previous cycle and the current cycle; and
a digital logic circuit, coupled to the flip-flop circuit, and configured to output the control signal according to the input data of the previous cycle and the current cycle.

14. The sense amplifier circuit according to claim 1, wherein the sense amplifier serves as a potential converter of a display driver circuit.
